(19) United States
(12) Patent Application Publication
(10) Pub. No.: US 2026/0169049 A1
(43) Pub. Date: Jun. 18, 2026

(54) METHOD FOR DETECTING HIGH IMPEDANCE FAULT AND ANALYZING INTERPRETABILITY OF POWER DISTRIBUTION NETWORK

(71) Applicant: Beijing Jiaotong University, Beijing (CN)

(72) Inventors: Xiaojun WANG, Beijing (CN); Changyu LIU, Beijing (CN); Zhao LIU, Beijing (CN); Dahai ZHANG, Beijing (CN); Fangyuan SI, Beijing (CN); Min CHEN, Beijing (CN); Guomin LUO, Beijing (CN)

(73) Assignee: Beijing Jiaotong University, Beijing (CN)

(21) Appl. No.: 19/534,735

(22) Filed: Feb. 9, 2026

(30) Foreign Application Priority Data
Apr. 11, 2025 (CN) 202510451431.8

(51) Int. Cl. G01R 31/08

(52) U.S. Cl. CPC G01R 31/085; G01R 31/088

(57) ABSTRACT

The present disclosure provides a method for detecting high impedance faults and analyzing interpretability of power distribution network. The method performs decomposition and reconstruction on original transient zero-sequence current signal by: using a method of improved complete ensemble empirical mode decomposition with adaptive noise to generate a reconstructed transient zero-sequence current signal; constructing a time convolutional network model based on the reconstructed transient zero-sequence current signal and outputting a fault detection result; and further constructing a score weighted class activation mapping method and performing qualitative analysis and quantitative calculation on detection criteria of model, and interpretability of data-driven fault detection scheme is fed back in a closed loop. The present disclosure has high detection accuracy and interpretability under different operating conditions, and is suitable for detection and analysis of high impedance faults in complex environments of power distribution networks.

### CROSS-REFERENCE TO RELATED APPLICATION

This application claims priority to Chinese Patent Application No. 202510451431.8, filed on Apr. 11, 2025, which is hereby incorporated by reference in its entirety.

### TECHNICAL FIELD

The present disclosure relates to the field of fault diagnosis and artificial intelligence technology for power distribution networks, particularly to method for detecting high impedance fault and analyzing interpretability of power distribution network.

### BACKGROUND ART

Power distribution networks have numerous lines, complex structures, and are close to the ground, which can cause high impedance faults due to non-metallic conductive medium such as grass, cement, and concrete. Due to the large transition impedance and susceptibility to harmonic interference of high impedance faults, their fault features are weak and similar to disturbance signals caused by conventional switching events such as load switching, capacitor switching, and excitation inrush current, making it difficult to effectively detect and promptly handle the high impedance faults. If high impedance faults persist over an extended period, they may damage equipment, trigger fires, and even exacerbate the scope of the fault, resulting in serious losses. Therefore, researching sensitive and reliable high impedance fault detection schemes is of great significance for ensuring the safe and reliable operation of power distribution network.

At present, according to the differences in feature analysis dimensions of high impedance fault detection schemes in power distribution networks, these schemes can be mainly divided into two categories: one is the indicator threshold method based on features of electrical quantity, and the other is the artificial intelligence method driven by data. The indicator threshold method quantifies and analyzes the differences in electrical information such as voltage and current before and after faults in the time domain, frequency domain, and time-frequency domain, and sets feature thresholds to detect high impedance faults. However, the above methods rely on single feature quantity or local features to construct criteria, and the feature thresholds are usually manually set. In complex operating scenarios such as increasingly complex system structures and measurement noise interference, classification blind spots are prone to occur, and universality of the above methods needs to be further expanded. In recent years, the artificial intelligence technology driven by data has continuously developed, providing new research ideas for solving high impedance fault detection problems. Artificial intelligence methods do not rely on complex mechanism analysis and can fit non-linear mapping relationships between input samples and output results from massive data, thereby achieving fast and accurate fault detection. Scholars have applied artificial intelligence to high impedance fault detection, such as support vector machines, artificial neural networks, convolutional neural networks, etc.

However, existing methods generally focus on the application of artificial intelligence algorithms, with models resembling “black boxes” and problems such as low confidence level and weak interpretable basis for decision-making, which pose risks for artificial intelligence algorithms to complete safety-sensitive tasks such as fault diagnosis for distribution network. And there is a lack of quantitative analysis and evaluation of knowledge of power operation and maintenance from the perspective of interpretability and a comprehensive consideration of multiple quantitative indicators to evaluate the effectiveness and trustworthiness of decision-making of model. Overall, although interpretability research on artificial intelligence in power has been preliminarily attempted in multiple fields, it is still in its infancy in the field of fault diagnosis in power distribution networks.

### SUMMARY

The purpose of the present disclosure is to provide a method for detecting high impedance fault and analyzing interpretability of power distribution network, in order to overcome the problems in the background art. The effectiveness of the proposed solution and applicability of the proposed solution in real scenarios have strong application value.

To achieve the above objectives, the present disclosure provides a method for detecting high impedance fault and analyzing interpretability of power distribution network, including following steps:
step S1: performing decomposition and reconstruction on original transient zero-sequence current signal by using a method of improved complete ensemble empirical mode decomposition with adaptive noise to generate a reconstructed transient zero-sequence current signal;
step S2: constructing a time convolutional network model based on the reconstructed transient zero-sequence current signal generated in step S1 and outputting a fault detection result; and
step S3: generating an attribution heatmap by using a score weighted class activation mapping method and based on the fault detection result outputted in step S2, analyzing a correlation between the reconstructed transient zero-sequence current signal and the fault detection result, and constructing a quantitative evaluation indicator;
where the step S3 comprises steps S31 to S33: step S31: generating a class activation mapping map by using linearly weighted fusion of feature-fused weights and feature maps, when the score weighted class activation mapping method is performed;
step S32: calculating an attribution value of a sampling point of each portion of time sequence of the reconstructed transient zero-sequence current signal; and
step S33: further constructing the quantitative evaluation indicator based on the attribution value calculated in step S32.

In some embodiments, step S1 specifically includes:
step S11: adding Gaussian white noise to the original transient zero-sequence current signal and calculating a residual value and a modal component in a first decomposition;
step S12: repeating a process of adding Gaussian white noise until the original transient zero-sequence current signal cannot be decomposed, and decomposing the original transient zero-sequence current signal into a sum of multiple components and multiple residuals of intrinsic mode function (IMF); and
selecting components corresponding to a value of IMF greater than or equal to 5 to form the reconstructed transient zero-sequence current signal.

In some embodiments, the time convolutional network model includes sequentially connected an input layer, multiple TCN modules, a 1×1 convolutional layer, a Flatten layer, a Dense layer, and a Softmax layer.

In some embodiments, each of the multiple TCN modules includes: a causal-dilated convolutional layer, a weight normalization layer, a ReLU activation function, and a Dropout unit.

In some embodiments, a calculation method of the class activation mapping map includes:

$$L = ReLU ( {\sum }_{k} {α}_{k}^{c} {A}_{l}^{k} ) ;$$

where L represents the class activation mapping map; ReLU represents an activation function;

$${α}_{k}^{c}$$

represents a weight of channel; k represents an indicator of the channel; c represents a category of interest;

$${A}_{l}^{k}$$

represents an activation output of a k-th channel in an l-th convolutional layer of a model.

In some embodiments, steps of constructing the quantitative evaluation indicator includes:
for a zero-sequence current waveform containing T sampling points, a moment of a signal crossing a zero point is defined as t₀, and an interval [t₀−ΔT, t₀+ΔT] of time sequence having the moment and ΔT sampling points before and after the moment is taken as an analysis window, and the interval [t₀−ΔT, t₀+ΔT] is defined as a set Ω₁ of key regions of a waveform crossing the zero point:

$${Ω}_{1} = \{ \vert t \vert t ∈ [ {t}_{0} - Δ T , {t}_{0} + Δ T ] \} ;$$

where an attribution value Ω₂ of features at a sampling-point moment t in a time sequence of a transient zero-sequence current is calculated, and a set Ω₂ of high attribution regions is defined as:

$${Ω}_{2} = \{ \vert t \vert S ( t ) > τ \} ;$$

where τ represents a threshold of attribution value;

and where an indicator ZAM reflecting a matching degree between the high attribution regions and the key regions, and an indicator KAR reflecting a proportion of the key regions in all attribution regions are defined as:

$$ZAM = \frac{\vert {Ω}_{1} ∩ {Ω}_{2} \vert}{\vert {Ω}_{2} \vert} ;$$

$$KAR = \frac{{\sum }_{t ∈ {Ω}_{1}} S ( t )}{{\sum }_{t ∈ T} S ( t )} ;$$

where |⋅| represents a number of elements contained in a set.

Therefore, the present disclosure adopts the abovementioned method for detecting high impedance fault and analyzing interpretability of power distribution network, and the beneficial technical effects are as follows:

The present disclosure can perform high-precision detection of high impedance fault in complex operating environments of new type of power distribution network, and visualize the decision-making mechanism of the model. On the one hand, the visualization results intuitively present the attention segments of the model to the zero-sequence current sequence, providing deterministic and tuning guidance for selection of hyperparameters. On the other hand, by combining quantitative evaluation indicators, the present disclosure explains the degree of dependence of the model on waveform distortion during the outage window in the detection results, and enhances the interpretability of the model decision-making process. The research results can provide technical support for the application of high impedance fault detection methods based on deep learning in practical systems.

### BRIEF DESCRIPTION OF THE DRAWINGS

FIG. 1 shows a topology of a 10 kV power distribution network.

FIG. 2 shows an Emanuel model.

FIG. 3 is a flowchart of the method for detecting high impedance fault and analyzing interpretability of power distribution network.

FIG. 4 shows performances of a model on a training set and a testing set during a training process.

FIG. 5 shows a confusion matrix of a model on a training set and a testing set; where (a) in FIG. 5 shows a confusion matrix on the training set, and (b) in FIG. 5 shows a confusion matrix on the testing set.

FIG. 6 shows visualization results of t-SNE; where (a) in FIG. 6 shows a visualization distribution result of an original dataset after dimensionality reduction by t-SNE algorithm; (b) in FIG. 6 shows a visualization distribution result of a dataset processed by one TCN module after dimensionality reduction by t-SNE algorithm; (c) in FIG. 6 shows a visualization distribution result of a dataset processed by two TCN modules after dimensionality reduction by t-SNE algorithm; and (d) in FIG. 6 shows a visualization distribution result of a dataset processed by three TCN modules after dimensionality reduction by t-SNE algorithm.

FIG. 7 shows decision-making mechanism analysis of samples under different operation conditions using Score-CAM; where (a) in FIG. 7 shows an attribution heatmap of samples of high impedance fault; (b) in FIG. 7 shows an attribution heatmap of samples of capacitor switching; (c) in FIG. 7 shows an attribution heatmap of samples of load switching; and (d) in FIG. 7 shows an attribution heatmap of samples of inrush current.

FIG. 8 shows decision-making criteria for different convolution kernel sizes; where (a) in FIG. 8 shows an attribution heatmap when the convolution kernel size is 1; (b) in FIG. 8 shows an attribution heatmap when the convolution kernel size is 3; and (c) in FIG. 8 shows an attribution heatmap when the convolution kernel size is 5.

FIG. 9 shows a residual block structure in TCN.

### DETAILED DESCRIPTION OF THE EMBODIMENTS

The following provides further explanation of the technical solution of the present disclosure through the accompanying drawings and embodiments.

Unless otherwise defined, the technical or scientific terms used in the present disclosure shall have the usual meanings as understood by those skilled in the art to which the present disclosure belongs.

### Embodiment 1

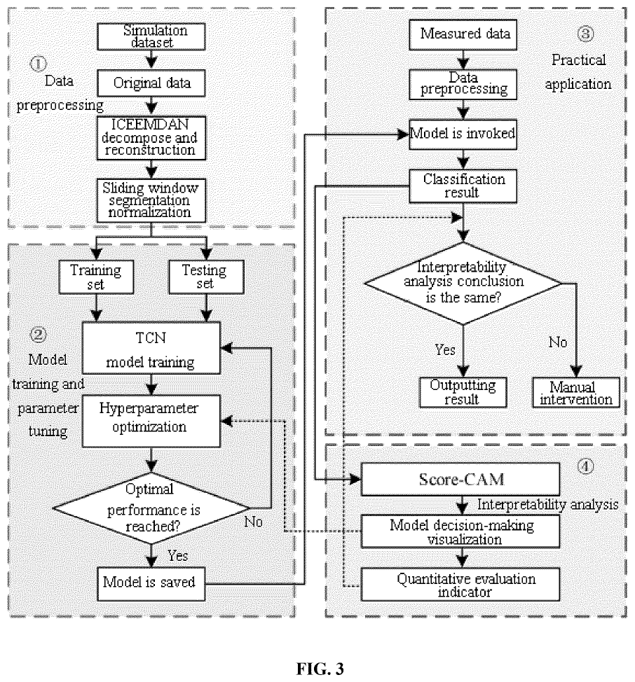

As shown in FIG. 3, a flowchart of a method for detecting high impedance fault and analyzing interpretability of power distribution network is provided. The flowchart includes four stages: data preprocessing, model training and parameter tuning, practical application, and interpretability analysis.

The data preprocessing stage: Measurement devices are used to collect original transient zero-sequence current signals under high impedance faults and normal disturbance conditions. Random noise is added into the original transient zero-sequence current signals to simulate the complex operation environment of the power distribution network. The noise-added original transient zero-sequence current signals are decomposed and reconstructed through the Improved Complete Ensemble Empirical Mode Decomposition with Adaptive Noise (ICEEMDAN) algorithm. Considering the uncertainty of occurrence moment of the actual system fault and the action delay of startup of the recording device, a sliding window segmentation is used to process the reconstructed transient zero-sequence current signals (the time window used in this embodiment is 40 ms), and Equation (1) is used to normalize the segmented transient zero-sequence current signal x:

$${x}_{i}^{′} = \frac{{x}_{i} - {x}_{min}}{{x}_{max} - {x}_{min}} ; \qquad ( 1 )$$

where xₘₐₓ and xₘᵢₙ represent a maximum value and a minimum value of a transient zero-sequence current signal x before normalization, respectively; xᵢ and xᵢ′ represent a value of an i-th element of the zero-sequence current signal x before normalization and a value of an i-th element of a zero-sequence current signal xᵢ′ after normalization, respectively. The above operations can reduce the differences in order of magnitude in electrical quantities, making the model more focused on trend of data changes and improving model performance.

Unlike traditional empirical mode decomposition (EMD) methods, ICEEMDAN improves the stability and accuracy of the decomposition process by optimizing noise addition and decomposition processes. It can effectively solve mode aliasing while reducing residual noise in intrinsic mode components, further highlighting features of each component in time domain and frequency domain. The present disclosure adopts the ICEEMDAN method to decompose and reconstruct the noise-added transient zero-sequence current signals, including following steps S11 to S12.

In step S11, the transient zero-sequence current signal to be decomposed is defined as i₀, where E_{K}( ) represents a K-order intrinsic mode function (IMF) component after EMD decomposition. Gaussian white noise is added into i₀ and a residual value R₁ and a first mode component D₁ of a first decomposition are calculated:

$${i}_{0}^{( n )} = {i}_{0} + ε {E}_{K} ( {w}^{( n )} ) ; \qquad ( 2 )$$

$${R}_{1} = \frac{1}{N} {\sum }_{n = 1}^{N} ( {i}_{0} + ε {E}_{K} ( {w}^{( n )} ) ) ; \qquad ( 3 )$$

$${D}_{1} = {i}_{0} - {R}_{1} ; \qquad ( 4 )$$

where ε represents a signal-to-noise ratio of Gaussian white noise; w⁽ⁿ⁾ represents the added n-th group of Gaussian white noise; and N represents a total number of additions

In step S12, steps of adding noise in step S11 are repeated, and a residual value Rⱼ and a mode component Dⱼ of a j-th decomposition are calculated until further decomposition cannot be performed. Through the above steps, the transient zero-sequence current signal i₀ to be decomposed is decomposed into a sum of multiple IMF components and residuals.

Spectral analysis of each IMF component obtained from decomposition reveals that some IMF components contain signal features that are measurement noise features and have weak correlation with the original transient zero-sequence current signal. Therefore, the present disclosure selects components with a value of IMF greater than or equal to 5 for signal superposition to form a reconstructed signal, effectively filtering out noise interference while fully preserving fault features.

Model training and parameter tuning stage: The preprocessed dataset is divided into a training set and a testing set in a ratio of 4:1. A time convolutional network model is constructed. Samples of the training set is inputted into the model, and model training and hyperparameter tuning work are carried out. Cross entropy is used as a loss function and minimized through the Adam optimizer. When the loss function and accuracy tend to stabilize, weights of the model are saved for subsequent testing and application analysis.

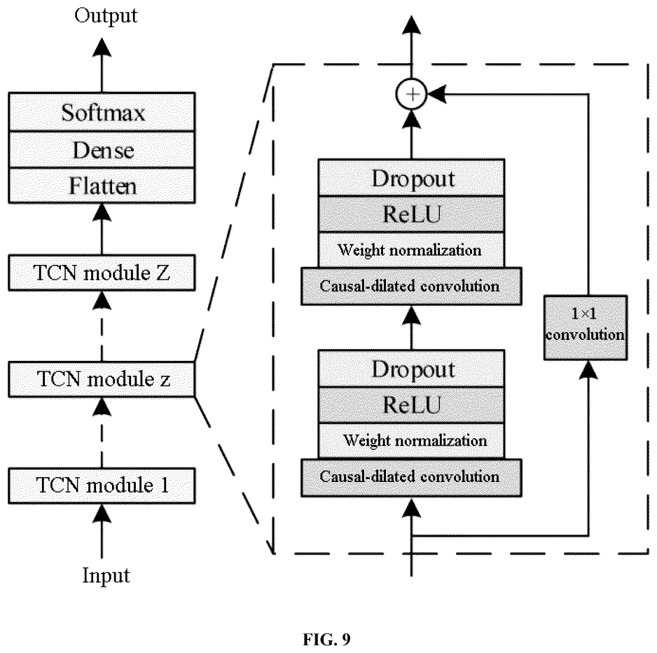

As shown in FIG. 9, the time convolutional network model includes following modules connected in sequence:
an input layer, which is used to receive the reconstructed transient zero-sequence current signal;
multiple TCN modules;
a 1×1 convolutional layer, which is used to adjust the feature dimension;
a Flatten layer, which is used to flatten multi-dimensional features;
a Dense layer, which is used for fully connected operations; and
a Softmax layer, which is used to output probabilities of classification.

Each TCN module includes:
a causal-dilated convolutional layer, which is used to extract features of time sequence;
a weight normalization layer, which is used to stabilize the training process;
a ReLU activation function, which is used to introduce nonlinearity; and
a Dropout unit, which is used to prevent overfitting.

Practical application stage: The transient zero-sequence current signals to be detected are collected and data preprocessing is performed, then the preprocessed data is inputted into a trained and saved model and classification results are output.

Interpretability analysis stage: The Score-CAM method is used to analyze decision-making results of the model. The attribution values of features in time sequence of the transient zero-sequence current at each sampling point moment. It is further clarified that which parts of the time sequence dominate or influence the sample classification results. By combining visualization methods, the impact of decision-making criteria of the model and hyperparameter settings on classification results, thereby intuitively reflecting the intrinsic correlation between input features and output categories.

In practical applications, reasonable thresholds can be set for ZAM and KAR to quantify the model's attention to the outage distortion properties of high impedance faults and evaluate the reliability of classification results of the model. By comparing the output results of the model with the attribution features of interpretability analysis, the controllability and credibility of the fault detection process can be enhanced. Specifically, if the classification result output by the model is a high impedance fault, but the indicators ZAM and KAR of the sample are both lower than the threshold setting, it indicates that the model's decision-making does not mainly rely on the features of key regions, indicating insufficient attention to the core features of high impedance faults, and there may be a risk of misjudgment. If the discrimination result outputted by the model is not a high impedance fault, but the indicators are higher than the threshold setting, it indicates that the model has accurately focused on the zero-point distortion features, but the final classification result has not been determined as a high impedance fault, which may mean a risk of omission judgment. In the above situations, manual intervention mechanism can be triggered to arrange technical personnel to conduct in-depth review of the entire fault diagnosis process, further analyze the discrimination criteria of the model, and clarify the potential sources of problems. This method effectively reduces the risk of misjudgment and omission judgment, and improves the accuracy and credibility of high impedance fault detection.

The Score-CAM uses a method of linearly weight fusing feature fused weights and feature maps to generate class activation mapping maps, achieving more stable interpretation effects. For a given time convolutional network model, the input and output of the model are defined as x and Y, respectively, and Y=f(x) is satisfied. The k-th channel of the l-th convolutional layer is selected and an activation corresponding to the k-th channel is defined as

$${A}_{l}^{k} .$$

For a know input xᵢ, a contribution

$$C ( {A}_{l}^{k} ) of {A}_{l}^{k}$$

to the output Y can be defined as:

$$C ( {A}_{l}^{k} ) = f ( x ∘ {H}_{l}^{k} ) - f ( {x}_{i} ) \qquad ( 5 )$$

Where ∘ represents an Hadamard product; and

$${H}_{l}^{k}$$

represents a vector with the same shape as xᵢ, and

$${H}_{l}^{k}$$

is expressed as follows:

$${H}_{l}^{k} = s [ Up ( {A}_{l}^{k} ) ] ; \qquad ( 6 )$$

where the function s[.] represents the normalization operation, mapping each element to the [0,1] interval; and the function Up(.) represents that up-sampling is performed in

$${A}_{l}^{k} .$$

The category of interest c is selected, and a formula for calculating the class activation map of Score-CAM can be defined as:

$$L = ReLU ( {\sum }_{k} {α}_{k}^{c} {A}_{l}^{k} ) ; \qquad ( 7 )$$

where L represents the class activation mapping map; ReLU represents the activation function;

$${α}_{k}^{c}$$

represents weight of the channel; k represents index of the channel; and

$${A}_{l}^{k}$$

represents the activation output of the k-th channel in the l-th convolutional layer of the model.

The weight of each channel

$${α}_{k}^{c} = C ( {A}_{l}^{k} )$$

can determine the specific category information contained in the class activation map; and ReLU(⋅) represents the activation function used to remove neurons that are useless for the class of interest c.

The present disclosure utilizes Score-CAM to analyze the decision-making results of a fault detection model based on a time convolutional network, and calculates the attribution values of features at each sampling point moment in time sequence of the transient zero-sequence current using Equations (5)-(7). Then the correlation between input samples and detection results is analyzed.

The class activation map generated by Score-CAM can provide stable visualization effects, showing key regions of focus for the model in the classification decision-making process, thereby providing guidance for hyperparameter tuning of the model. On the basis of this qualitative analysis, the present disclosure further constructs quantitative evaluation indicators based on the generated attribution result values, thereby providing more intuitive decision-making support for operation and maintenance personnel.

Firstly, for a transient zero-sequence current waveform containing T sampling points, a moment of signal crossing a zero point (the zero point is a time point at which the current sign of adjacent sampling points changes) is defined as t₀, and an interval [t₀−ΔT, t₀+ΔT] of time sequence having the moment and ΔT sampling points before and after the moment is taken as an analysis window, and the interval [t₀−ΔT, t₀+ΔT] is defined as a set Ω₁ of key regions of a waveform crossing the zero point:

$${Ω}_{1} = \{ t \vert t ∈ [ {t}_{0} - Δ T , {t}_{0} + Δ T ] \} ; \qquad ( 8 )$$

where an attribution value Ω₂ of features at a sampling-point moment t in a time sequence of a transient zero-sequence current is calculated according to Equations (5)-(7), and a set Ω₂ of high attribution regions is defined as:

$${Ω}_{2} = \{ t \vert S ( T ) > τ \} ; \qquad ( 9 )$$

where τ represents a threshold of attribution value, and the threshold of attribution value in this embodiment is 0.6.

An indicator ZAM reflecting a matching degree between the high attribution regions and the key regions, and an indicator KAR reflecting a proportion of the key regions in all attribution regions are further defined as:

$$ZAM = \frac{\vert {Ω}_{1} ∩ {Ω}_{2} \vert}{\vert {Ω}_{2} \vert} ;$$

$$KAR = \frac{{\sum }_{t ∈ {Ω}_{1}} S ( t )}{{\sum }_{t ∈ T} S ( t )} ;$$

where |⋅| represents a number of elements contained in a set.

From the analysis of Equations (10) and (11), it can be seen that ZAM measures whether the model accurately focuses on the distortion features of the waveform near the zero point by evaluating whether points having high attribution values are concentrated in key regions. The larger the value of ZAM, the more the points having high contribution attribution values of the model are mainly distributed in key regions, indicating that the model has extracted more discriminative features in the key regions where the waveform crosses the zero point. On the contrary, if the ZAM value is low, indicating that the points having high contribution attribution values of the model are scattered and may rely on information from other regions for classification, reducing the dependence on key features at zero-crossing point. KAR reflects the proportion of key region's attribution values in the global attribution values, measuring the degree of dependence of the model on zero-crossing key regions in the overall decision-making process. The larger the value of KAR, the more prioritize the model to rely on the waveform features of the zero-crossing key region in classification decision-making, rather than the noise or redundant information of other non key regions, thus reflecting the global importance of the model to the features of key regions.

Overall, KAR reflects the proportion of features of key regions in the overall attribution values, measuring the model's global attention preference, while ZAM reflects whether the model accurately focuses on high contribution points in key regions, measuring the model's ability to capture local features. The combination of KAR and ZAM can effectively evaluate the attribution feature distribution and decision-making criteria of the model in high impedance fault detection.

The present disclosure will be further explained through simulation experiments.

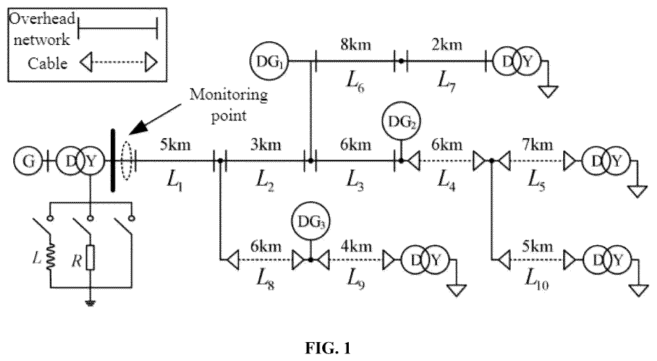

A simulation model of the 10 kV power distribution network as shown in FIG. 1 is established in MATLAB/Simulink to simulate high impedance faults and disturbances and conduct subsequent analysis. This model includes a power source G, a transformer (DYn11 connection is used, and high-voltage side D represents delta connection, and low-voltage side Y represents star connection), lines (L₁-L₁₀), a load (connected to the grid through transformer), and distributed power sources (DG₁-DG₃). Where the transformer capacity is 250 MVA, the transformation ratio is 110 kV/10.5 kV, and the neutral point adopts the grounding method of arc suppression coil (R and L respectively represent the impedance and inductance parameters of the arc suppression coil, with a compensation degree of 8%). The lengths of each line have been marked in the figures, and the line parameters are shown in Table 1. At the monitoring point, a μPMU device with a sampling frequency of 10 kHz is used to obtain transient zero-sequence current signal, which has a sampling frequency of 10 KHz.

TABLE 1
Line Parameters

| | Phase | Resistance/ | Inductance/ | Capacitance/ |
|---|---|---|---|---|
| Category | sequence | (Ω · km − 1) | (mH · km − 1) | (μF · km − 1) |
| Overhead | Positive | 0.1700 | 1.2100 | 0.0097 |
| network | sequence | | | |
| | Zero | 0.2300 | 5.4800 | 0.0060 |
| | sequence | | | |
| Cable | Positive | 0.2650 | 0.2550 | 0.1700 |
| | sequence | | | |
| | Zero | 2.5400 | 1.0190 | 0.1530 |
| | sequence | | | |

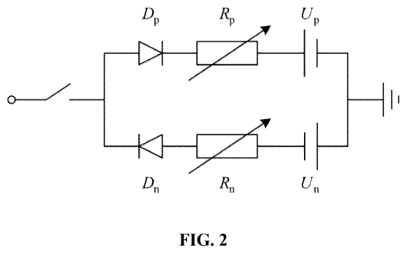

Based on the above simulation of power distribution network, a simulation sample library can be established, with parameters shown in Table 2. Where the high impedance fault is simulated using the Emanuel model shown in FIG. 2. In FIG. 2, Uₚ and Uₙ are direct current (DC) voltage sources with ±10% fluctuation to simulate the asymmetry and nonlinearity of arc voltage and fault current; Rₚ and Rₙ are time-varying resistors used to simulate impedances of fault arc; Dₚ and Dₙ are ideal diodes, which together with Uₚ and Uₙ form the current paths for the positive and negative half-cycles of the circuit.

TABLE 2
Sample Parameters

| | | Disturbance | | | High |
|---|---|---|---|---|---|
| | | Capacitance | Load | Inrush | impedance |
| Category | Normal | switching | switching | current | fault |
| Position | / | L₁~L₁₀ | L₇~L₁₀ | L₇~L₁₀ | L₁~L₁₀ |
| Initial | / | 0°, 30°, 45°, 90°, 180° | | | |
| phase | | | | | |
| angle | | | | | |
| Parameter | / | 1MVar, | 0.1 MW, | YNd1, | Uₚ, Uₙ, Rₚ, Rₙ |
| value | | 3MVar | 0.25 MW, | YNd11 | |
| | | | 1 MW | | |
| Number | 350 | 400 | 240 | 160 | 600 |
| of | | | | | |
| samples | | | | | |

By changing the access position, initial phase angle, and sample parameters, simulation samples that occur under different transition impedances, different line types, and different positions can be fully obtained. The data within a 0.2 s time window before and after the occurrence of the switch event (including 2 cycles before the fault and 8 cycles after the fault) is uniformly captured, and a 40 ms time window is used to segment. After decomposition and reconstruction using the ICEEMDAN method, labels 0, 1, and 2 are assigned according to settings of the simulation, these labels corresponds to normal, disturbance (including capacitor switching, load switching, inrush current), and high impedance fault, respectively. Finally, the dataset will be divided into a training set and a testing set in a ratio of 4:1. Considering the certain imbalance between the training and testing samples, using only overall accuracy as an indicator to evaluate performance of the model is obviously biased. Therefore, precision, recall, and F1 score can be supplemented to comprehensively evaluate performance of the model, and F1 score is used to evaluate the classification performance of the fault localization model.

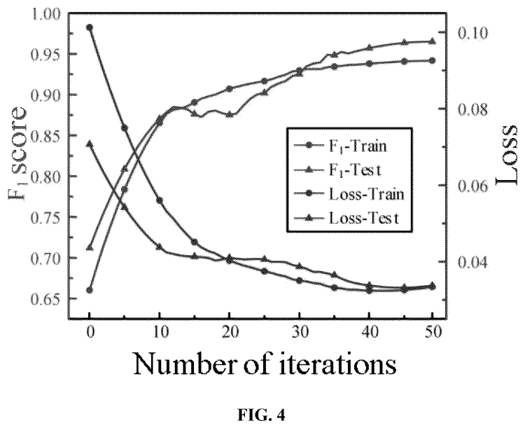

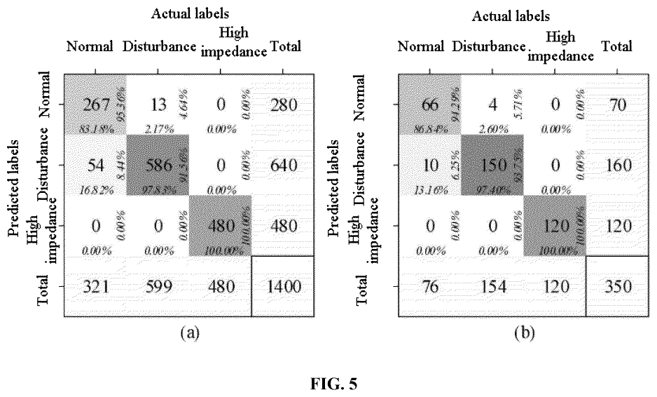

FIG. 4 shows performances of the model on the training and testing sets during the training process, with the abscissa representing the number of iterations, totaling 50 rounds; and the ordinates represent F1 score and loss, respectively. From FIG. 4, it can be observed that the loss curve decreases significantly in the early stages of training, but tends to stabilize after 40 iterations. To ensure stable effect of the model, this embodiment selects the model saved during the 48th iteration as the final model for subsequent testing work. The confusion matrix of the exported model on the training and testing sets is shown in FIG. 5. It can be seen that the overall accuracy of the model on the testing set reaches 96%, the precision of the model on the testing set reaches 94.75%, the recall rate of the model on the testing set reaches 96.01%, and the F1 score of the model on the testing set reaches 95.32%. This indicates that the model can maintain a high level of generalization ability under different operating conditions, and there is no misjudgment or omission judgment of high impedance fault categories, which preliminarily verifies the effectiveness of the high impedance fault detection scheme proposed by the present disclosure.

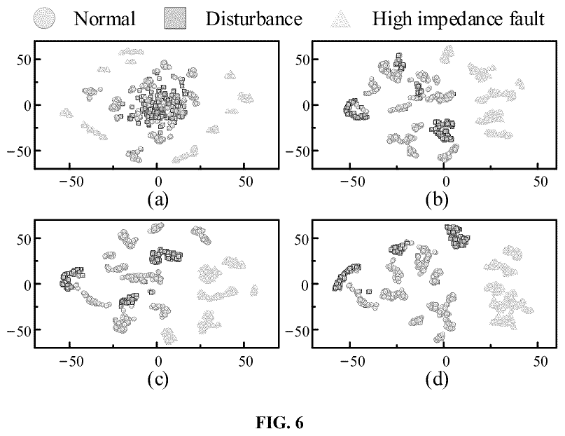

To further validate the effectiveness of the proposed scheme, the t-distribution random nearest neighbor embedding algorithm is used to perform dimensionality reduction visualization on the original data and the data processed by different TCN modules. The results are shown in FIG. 6. Different colors represent different categories, and the coordinate axis only represents the distribution of data points on a two-dimensional plane after dimensionality reduction, and is dimensionless. (a) in FIG. 6 indicates that the original samples exhibit significant disorder in both feature dimension and distribution pattern and are randomly dispersed in a low dimensional visualization space, lacking clear clustering trends. However, as the depth of the feature extraction layer increases (as shown in (b) to (d) in FIG. 6), the sample points begin to exhibit a clustering trend. The distance between sample points of the same class gradually decreases, forming a clear clustering structure. At the same time, the distance between different categories significantly increases, gradually establishing clear classification boundaries. The above transformation process fully demonstrates that the clustering effect of the samples gradually strengthens, indicating that the model designed by the present disclosure can fully explore the hidden features in time sequence of the transient zero-sequence current, and demonstrate superior feature extraction and classification capabilities in fault detection tasks.

The proposed method is compared with common fault detection models to fully validate the advantages of the proposed scheme, including model classification effect and testing time. Considering the randomness in the training and testing processes of the model, multiple repeated tests are conducted on the model and an average value is calculated. The results are shown in Table 3. Where the testing time is the average calculation time of the samples in the testing set. The results indicate that the proposed method has substantial advantages in computational efficiency and accuracy compared to SVM and ANN based methods. In addition, although CNN shows better performance in terms of testing time, the TCN model demonstrates significant superiority in classification effect. It is worth noting that when considering the safe and reliable operation of actual power distribution networks, consequences of missed and false detections are more serious than those of delayed detections. Therefore, sacrificing a certain amount of testing time to improve the accuracy of fault detection is still reasonable.

TABLE 3
Comparison of the effectiveness of different classification methods

| | | | Recall | | Testing | |
|---|---|---|---|---|---|---|
| Scheme | Accuracy | Precision | rate | F1 score | time | |
| SVM | 90.86% | 93.09% | 85.30% | 87.41% | 1.5 | ms |
| ANN | 88.29% | 93.20% | 80.48% | 82.41% | 3 | ms |
| CNN | 91.14% | 94.59% | 85.24% | 87.58% | 0.6 | ms |
| Method of | 96.00% | 94.75% | 96.01% | 95.32% | 0.9 | ms |
| the present | | | | | | |
| disclosure | | | | | | |

The Score-CAM algorithm is used to analyze the operation mechanism of the time convolutional network. That is, for the reconstructed transient zero-sequence current signal, the contribution of each time-sequence segment to the classification result is calculated, and an attribution heatmap is constructed based on this, in order to clearly distinguish the feature segments that play a key role in the decision-making results, thereby helping operation and maintenance personnel understand the decision-making criteria of the model. In the attribution heatmap, the range of attribution values is in the (0,1) interval. A larger attribution value means that the sampling point has a more significant impact on the decision-making of the model, and size of the attribution value is represented by different colors. According to this standard, the impact of each segment of time sequence in the transient zero-sequence current on the decision-making results of the model can be qualitatively evaluated. On the basis of this, a quantitative analysis can be conducted by combining ZAM and KAR to quantitatively evaluate the model's attention to the zero-crossing interval of the waveform, in order to analyze the differences in attribution patterns among different types of samples.

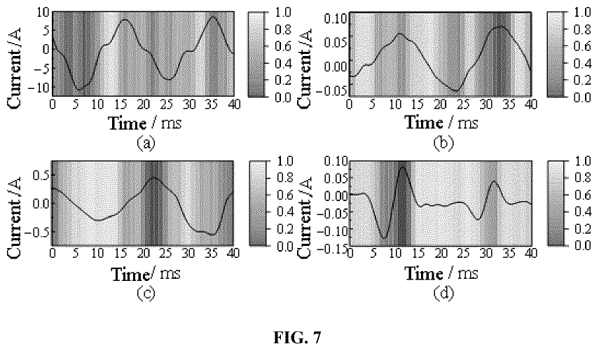

FIG. 7 illustrates the operational mechanism of the TCN model for fault classification using Score-CAM. It can be seen that the key factor affecting the classification results of the model is not the peak or valley region, but the varying degrees of distortion near the zero-crossing point of the waveform. In the high impedance fault condition shown in (a) of FIG. 7, when the transient zero-sequence current shows a horizontal trend and returns to a sinusoidal change for a period of time after the zero-crossing point, this outage property can be effectively detected by the model and serves as a key basis for high impedance fault detection. From this, it can be seen that the TCN model can obtain key waveform features of different types of samples, providing a visual decision-making basis for the model to make judgments for corresponding category.

From a quantitative analysis perspective, for samples of high impedance fault shown in (a) of FIG. 7, values of indicators ZAM and KAR are 0.69 and 0.7, respectively. For samples of capacitance switching shown in (b) of FIG. 7, values of indicators ZAM and KAR are 0.61 and 0.61, respectively. For samples of load switching shown in (c) of FIG. 7, values of indicators ZAM and KAR are 0.59 and 0.63, respectively. For samples of inrush current shown in (d) of FIG. 7, values of indicators ZAM and KAR are 0.58 and 0.56, respectively. From this, it can be seen that the indicators of samples of high impedance fault are significantly higher than those of samples of other disturbance categories, indicating that the high contribution attribution values of the model are mainly concentrated in the zero-crossing region of the waveform, which is consistent with the electrical property of high impedance faults. This indicates that the attribution results of Score-CAM have a certain degree of physical interpretability. In contrast, both indicators of samples of disturbance category are lower than HIF (high impedance fault), and the indicators of samples of IC (samples of inrush current) are the smallest. From (d) in FIG. 7, it can be seen that the high attribution value regions of samples of inrush current are evenly distributed throughout the entire time axis, indicating that the model's classification of such disturbance samples relies more on global features rather than being limited to zero-crossing regions of waveform.

Overall, FIG. 7 also indicates a strong positive correlation between indicators ZAM and KAR, meaning that when the proportion of attribution values in the zero-crossing region of the waveform is high, the high contribution attribution points output by the classification results tend to be more concentrated in the key regions where the waveform crosses the zero point. Therefore, the above quantitative indicators collectively reflect the degree of attention that the model pays to key regions during classification decision-making, and can serve as important quantitative indicators to measure the rationality of the model's decision-making criteria, providing more intuitive and reliable decision-making support for operation and maintenance personnel.

Usually, the selection of model hyperparameters (such as convolution kernel size, expansion coefficient, etc.) is blind due to the lack of clear theoretical guidance. Researchers mostly rely on continuous combination and trial and error to determine appropriate hyperparameters. This process requires a significant investment of computing resources and time costs, and it is difficult to obtain the optimal parameter combination. The interpretability method adopted in the present disclosure can intuitively analyze the intrinsic relationship between hyperparameters and model performance, effectively avoiding blind trial and error while providing clear and traceable criteria for the reasonable selection of hyperparameters, further improving the efficiency of model optimization.

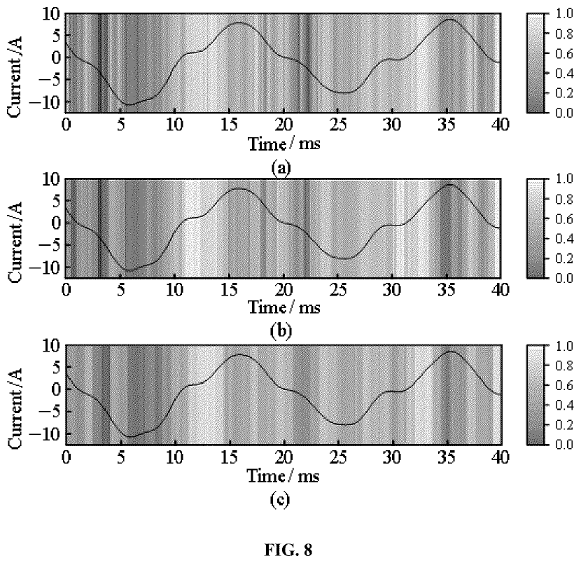

In the process of optimizing the parameters of convolution kernel size, it is found that models with different convolution kernel sizes have a certain proportion of misjudging high impedance faults as disturbances. For a sample of high impedance fault, the models with convolution kernel sizes of 1 and 5 misjudge the sample, while the model with convolution kernel size of 3 gives the correct classification result. FIG. 8 shows visualization analysis results of the diagnostic results of the sample for the trained models under the three types of different convolution kernel sizes mentioned above. As shown in FIG. 8, as the size of the convolution kernel gradually increases, the model can extract features in longer temporal segments. If the convolution kernel is too small, it can only capture local features in the sample, which is too fragmented. When the convolution kernel is set too large, it is easy to shift the feature region that the model pays attention to or capture interfering features. When the size of the convolution kernel is set to 3, the model can accurately cover the zero-crossing distortion region that determines the classification of the sample as a high impedance fault, thereby providing the correct classification result.

It is worth noting that the contents not elaborated in detail in the present disclosure are all prior art and are well-known to those skilled in the art.

Therefore, the present disclosure adopts the abovementioned method for detecting high impedance fault and analyzing interpretability of power distribution network, which has high detection accuracy and interpretability under different operating conditions, and is suitable for detection and analysis of high impedance fault in complex environments of power distribution network.

Finally, it should be noted that the above embodiments are only used to illustrate the technical solution of the present disclosure and not to limit it. Although the present disclosure has been described in detail with reference to the preferred embodiments, those skilled in the art should understand that modifications or equivalent substitutions can still be made to the technical solution of the present disclosure, and these modifications or equivalent substitutions cannot make the modified technical solution deviate from the spirit and scope of the technical solution of the present disclosure.

What is claimed is:

1. A method for detecting high impedance faults and analyzing interpretability of power distribution networks, comprising following steps:
step S1: performing decomposition and reconstruction on an original transient zero-sequence current signal by using a method of complete ensemble empirical mode decomposition with adaptive noise to generate a reconstructed transient zero-sequence current signal;
step S2: constructing a time convolutional network model based on the reconstructed transient zero-sequence current signal generated in step S1 and outputting a fault detection result; and
step S3: generating an attribution heatmap by using a score weighted class activation mapping method and based on the fault detection result outputted in step S2, analyzing a correlation between the reconstructed transient zero-sequence current signal and the fault detection result, and constructing a quantitative evaluation indicator;
wherein the step S3 comprises steps S31 to S33:
step S31: generating a class activation mapping map by using linearly weighted fusion of feature-fused weights and feature maps, when the score weighted class activation mapping method is performed;
step S32: calculating an attribution value of a sampling point of each portion of time sequence of the reconstructed transient zero-sequence current signal; and
step S33: further constructing the quantitative evaluation indicator based on the attribution value calculated in step S32.

2. The method for detecting high impedance faults and analyzing interpretability of power distribution networks according to claim 1, wherein step S1 specifically comprises:
step S11: adding Gaussian white noise to the original transient zero-sequence current signal and calculating a residual value and a modal component in a first decomposition;
step S12: repeating a process of adding Gaussian white noise until the original transient zero-sequence current signal cannot be decomposed, and decomposing the original transient zero-sequence current signal into a sum of a plurality of components and a plurality of residuals of intrinsic mode function (IMF); and
selecting components corresponding to a value of IMF greater than or equal to 5 to form the reconstructed transient zero-sequence current signal.

3. The method for detecting high impedance faults and analyzing interpretability of power distribution networks according to claim 1, wherein the time convolutional network model comprises sequentially connected an input layer, a plurality of TCN modules, a 1×1 convolutional layer, a Flatten layer, a Dense layer, and a Softmax layer.

4. The method for detecting high impedance faults and analyzing interpretability of power distribution networks according to claim 3, wherein each of the plurality of TCN modules comprises: a causal-dilated convolutional layer, a weight normalization layer, a ReLU activation function, and a Dropout unit.

5. The method for detecting high impedance faults and analyzing interpretability of power distribution networks according to claim 1, wherein a calculation method of the class activation mapping map comprises:
$$L = ReLU ( {\sum }_{k} {α}_{k}^{c} {A}_{l}^{k} ) ;$$
wherein L represents the class activation mapping map; ReLU represents an activation function;
$${α}_{k}^{c}$$
represents a weight of channel; k represents an indicator of the channel; c represents a category of interest;
$${A}_{l}^{k}$$
represents an activation output of a k-th channel in an l-th convolutional layer of the time convolutional network model.

6. The method for detecting high impedance faults and analyzing interpretability of power distribution networks according to claim 1, wherein steps of constructing the quantitative evaluation indicator comprises:
for a zero-sequence current waveform containing T sampling points, a moment of a signal crossing a zero point is defined as t₀, and an interval [t₀−ΔT, t₀+ΔT] of time sequence having the moment and ΔT sampling points before and after the moment is taken as an analysis window, and the interval [t₀−ΔT, t₀+ΔT] of time sequence is defined as a set Ω₁ of key regions of a waveform crossing the zero point:
$${Ω}_{1} = \{ t \vert t ∈ [ {t}_{0} - Δ T , {t}_{0} + Δ T ] \} ;$$
wherein an attribution value Ω₂ of features at a sampling-point moment t in a time sequence of a transient zero-sequence current is calculated, and a set Ω₂ of high attribution regions is defined as:
$${Ω}_{2} = \{ t \vert S ( t ) > τ \} ;$$
wherein τ represents a threshold of attribution value;
and wherein an indicator ZAM reflecting a matching degree between the high attribution regions and the key regions, and an indicator KAR reflecting a proportion of the key regions in all attribution regions are defined as:
$$ZAM = \frac{\vert {Ω}_{1} ∩ {Ω}_{2} \vert}{\vert {Ω}_{2} \vert} ;$$
$$KAR = \frac{{\sum }_{t ∈ {Ω}_{1}} S ( t )}{{\sum }_{t ∈ T} S ( t )} ;$$
wherein |⋅| represents a number of elements contained in a set.
